(19) United States
(12) Patent Application Publication
(10) Pub. No.: US 2009/0080167 A1
(43) Pub. Date: Mar. 26, 2009

(54) PRINTED CIRCUIT BOARD SECURING STRUCTURE AND TUNER UNIT

(76) Inventors: Tomotake KISHIDA, Nara (JP); Tsuyoshi Itaya, Osaka (JP)

Correspondence Address: BIRCH STEWART KOLASCH & BIRCH, PO BOX 747, FALLS CHURCH, VA, 22040-0747, US

(21) Appl. No.: 12/181,106

(22) Filed: Jul. 28, 2008

(30) Foreign Application Priority Data
Sep. 26, 2007 (JP) 2007-249550

(51) Int. Cl. H05K 7/14

(52) U.S. Cl. 361/752

(57) ABSTRACT

In one embodiment of a printed circuit board securing structure and a tuner unit according to the present invention, a chassis comprises a chassis frame that surrounds the lateral faces of a printed circuit board and a shield plate that partitions the space within the chassis frame, and circuit board holding parts for holding the printed circuit board between the circuit board holding parts and the shield plate are disposed on inner wall faces of the chassis frame. The circuit board holding parts are configured to be able to secure the printed circuit board from both faces.

### BACKGROUND OF THE INVENTION

This application claims priority under 35 U.S.C. §119(a) on Japanese Patent Application No. 2007-249550 filed in Japan on Sep. 26, 2007, the entire contents of which are herein incorporated by reference.

The present invention relates to a printed circuit board securing structure that secures to a chassis a printed circuit board such as a tuner circuit board for receiving high-frequency waves, and to a tuner unit equipped therewith.

A printed circuit board provided in an electronic device is generally held in the casing of the electronic device while being securely arranged on a frame or the like. As with a printed circuit board provided in a tuner for receiving high-frequency waves such as a tuner for receiving television signals or the like, when a printed circuit board is furnished with a high-frequency circuit and secured, the printed circuit board is held securely on a chassis having a chassis frame that surrounds the lateral faces of the printed circuit board.

In a conventional structure for securing a printed circuit board as disclosed in JP H3-48284A, JP S62-128690A, JP H4-79486A, JP H9-260884A or JP H1-121946A, a securing means for securing a printed circuit board is provided on a chassis frame that constitutes a chassis, the printed circuit board is held by the securing means, and the securing means and the printed circuit board are joined by soldering, thereby securing the printed circuit board.

Moreover, the chassis is sometimes furnished with a shield plate that partitions the space within the chassis frame. Here, with reference to FIG. 9, an instance of producing a tuner unit 100 is described using as an example a tuner for receiving television signals as a printed circuit board. FIG. 9 is an exploded perspective view schematically showing an example of a conventional printed circuit board securing structure that secures a printed circuit board to a chassis furnished with a chassis frame and a shield plate.

When producing the tuner unit 100, first, a resistor, a volume capacitor and like components that are not shown are mounted on a printed circuit board 101. Next, an air-core coil, a surface acoustic wave (SAW) filter and like insertion components which are not shown are inserted into the mounted printed circuit board 101. Finally, assembling work is performed to combine the chassis 102 with the printed circuit board 101 on which the insertion parts have been mounted.

The chassis 102 is furnished with, for example, a chassis frame 103 that surrounds the lateral faces of the printed circuit board 101; a shield plate 104 that partitions the space within the chassis frame 103; and a pair of shield lids 105 and 106 disposed on the chassis frame 103 so as to cover the printed circuit board 101 from both faces. On the edge of the shield plate 104 on the side facing the printed circuit board 101, protrusions 104a are provided that extend toward the printed circuit board 101. Moreover, with respect to the printed circuit board 101, protrusion-receiving holes 101a into which the protrusions 104a of the shield plate 104 are inserted are disposed in lands of the circuit board.

In the aforementioned assembling work, soldering of the protrusions 104a is performed on the lands of the circuit board while the protrusions 104a of the shield plate 104 in the chassis 102 are inserted into the protrusion-receiving holes 101a of the printed circuit board 101, thus making the chassis 102 and the printed circuit board 101 into a single body. At this time, a worker performs preliminary soldering on lands provided on the printed circuit board 101, and this presolder and the protrusions 104a of the chassis 102 are soldered manually.

However, there are the following disadvantages with a conventional printed circuit board securing structure of this kind. That is, there is a concern of soldering defects due to the variation in soldering quality created by manual operation, and when there is a soldering defect, repairing or like work therefor deteriorate production efficiency, thereby influencing as a consequence the production costs. For example, when producing a tuner or the like, the printed circuit board 101 and the chassis 102 are secured by soldering at about 7 to 10 places, and among these soldered portions, 3 to 5 places are often soldered manually. In terms of manual soldering, there are great differences among workers due to their abilities, posing a great possibility of creating many defects. Moreover, even if a soldered portion is faulty, since it is difficult to distinguish that faultily soldered portion from proper soldering by appearance, it has been difficult to detect soldering defects themselves.

When there is a request, for example, to change terminals 107 that are connected to the printed circuit board 101 while maintaining the circuit configuration of the printed circuit board, despite changing only the terminals 107, this change involves a design change of the entire chassis 102, and the design change requires time and cost.

Moreover, when a considerable change in a circuit is needed due to a severe required specification, advancement in characteristics and like reasons, it is necessary to manually replace chips using a soldering iron or the like that has been mounted on the printed circuit board 101 attached to the chassis 102. At the same time, even when making a small change in the circuit, the printed circuit board 101 produced before the circuit change is sometimes entirely replaced, thereby being wasteful.

### SUMMARY OF THE INVENTION

The present invention is directed to a printed circuit board securing structure for addressing the aforementioned problems, and a tuner unit having the securing structure. An object of the present invention is to enhance productivity by enabling manually soldered portions provided to secure a printed circuit board to be reduced. Furthermore, another object of the present invention is to enhance productivity by, even when the specification of a printed circuit board is changed, being able to flexibly respond to the specification change.

In order to achieve the aforementioned objects, the present invention provides printed circuit board securing structures of first and second embodiments and a tuner unit as follows.

### (1) Printed Circuit Board Securing Structure of the First Embodiment

A printed circuit board securing structure that secures a printed circuit board to a chassis, wherein the chassis is furnished with a chassis frame that surrounds the lateral faces of the printed circuit board and a shield plate that partitions the space within the chassis frame, and circuit board holding parts for holding the printed circuit board between the circuit board holding parts and the shield plate are provided on the inner wall faces of the chassis frame.

### (2) Printed Circuit Board Securing Structure of the Second Embodiment

A printed circuit board securing structure that secures a printed circuit board to a chassis, wherein the chassis is furnished with a chassis frame that surrounds the lateral faces of the printed circuit board and a shield plate that partitions the space within the chassis frame, the printed circuit board is divided into pieces so as to correspond to the space partitioned by the shield plate, and among the inner wall faces of the chassis frame and wall faces of the shield plate, on the faces that surround each divided circuit board piece of the printed circuit board, circuit board holding parts that are configured to be able to secure the printed circuit board from both faces are disposed.

### (3) Tuner Unit

A tuner unit furnished with the printed circuit board securing structure of the first or second embodiment of the present invention.

According to the printed circuit board securing structure of the first embodiment and the tuner unit furnished therewith of the present invention, since the circuit board holding parts for holding the printed circuit board between the circuit board holding parts and the shield plate are disposed on the inner wall faces of the chassis frame, the printed circuit board can be secured by the chassis frame, the shield plate and the circuit board holding parts. Therefore, the portions manually soldered for securing the printed circuit board can be reduced, thereby enabling productivity to be enhanced.

According to the printed circuit board securing structure of the second embodiment and the tuner unit furnished therewith of the present invention, the printed circuit board is divided into pieces so as to correspond to the space partitioned by the shield plate; among the inner wall faces of the chassis frame and the wall faces of the shield plate, on the faces enclosing each divided printed circuit board piece of the printed circuit board, the circuit board holding parts are disposed such that each circuit board piece can be secured from both faces, and therefore among the chassis frame and the shield plate, each circuit board piece can be secured by the circuit board holding parts and the other members enclosing the each circuit board piece. Therefore, portions manually soldered for securing the printed circuit board can be reduced, thereby enabling productivity to be enhanced, and at the same time, since the printed circuit board is divided into small pieces, even when there is a change in the specification of the printed circuit board, it is possible to flexibly respond to the specification change, and to that extent productivity can be enhanced.

In the printed circuit board securing structure of the first embodiment according to the present invention, the circuit board holding parts may be configured to be able to secure the printed circuit board from both faces. In this case, the printed circuit board can be secured by the chassis frame and the circuit board holding parts.

The following examples can be given as specific embodiments of the printed circuit board securing structures of the first and second embodiments according to the present invention.

That is, example embodiments include:
(a) an embodiment in which a terminal that is electrically connected to the printed circuit board is further provided, a through-hole into which the terminal is inserted is disposed in the chassis frame, and the terminal is provided so as to be insertable into and removable from the through-hole of the chassis frame; and
(b) an embodiment in which a terminal that is electrically connected to the printed circuit board and is fixed to the printed circuit board is further provided, a through-hole into which the terminal is inserted is disposed in the chassis frame, and the terminal is inserted into the through-hole of the chassis frame while being fixed to the printed circuit board.

In the case of embodiment (a), the terminal and the through-hole of the chassis frame may be configured to be fitted together by screwing. Moreover, in the through-hole of the chassis frame, a plurality of locking parts extending in the radially inward direction may be provided in the circumferential direction, and at the end of the terminal on the side of insertion into the through-hole, a plurality of engagement parts are provided in the circumferential direction in which when the terminal is inserted into the through-hole and rotated around the axis, the terminal is engaged rotatably around the axis and immovably in the axial direction with the plurality of the locking parts in the through-hole.

### BRIEF DESCRIPTION OF THE DRAWINGS

FIG. 1 is an exploded perspective view showing a schematic configuration of a tuner unit furnished with the printed circuit board securing structure according to Example 1 of the present invention.

FIG. 2 is a cross-sectional view schematically showing the circuit board holding parts in the printed circuit board securing structure shown in FIG. 1.

FIG. 3 shows an example of the circuit board holding parts configured to be able to secure a printed circuit board from both faces in the printed circuit board securing structure shown in FIG. 1 and is a cross-sectional view schematically showing the circuit board holding parts.

FIG. 4 is a perspective view schematically showing, in the printed circuit board securing structure shown in FIG. 1, an example of a configuration in which terminals are provided insertably into and removably from the through-holes of a chassis frame.

FIGS. 5A to 5C are figures schematically showing, in the printed circuit board securing structure shown in FIG. 1, another example of a configuration in which terminals are provided insertably into and removably from the through-holes of a chassis frame, in which FIG. 5A is a perspective view thereof, FIG. 5B is a side elevational view showing a manner of engagement between a terminal and a through-hole, and FIG. 5C is a cross-sectional view along line b-b of FIG. 5B.

FIG. 6 is an exploded perspective view showing a schematic configuration of the printed circuit board securing structure according to Example 2 of the present invention.

FIG. 7 shows an example of the circuit board holding parts in the printed circuit board securing structure shown in FIG. 6, and is a cross-sectional view schematically showing the circuit board holding parts.

FIG. 8 is an exploded perspective view schematically showing an example, in the printed circuit board securing structure shown in FIG. 6, of a configuration in which terminals are inserted into the through-holes of the chassis frame while the terminals are fixed to the printed circuit board.

FIG. 9 is an exploded perspective view schematically showing an example of a conventional printed circuit board securing structure in which a printed circuit board is secured to a chassis furnished with a chassis frame and a shield plate.

### DESCRIPTION OF THE PREFERRED EMBODIMENTS

Hereinbelow, preferred examples of the present invention are described with reference to the drawings. Each of the examples given below is an embodiment of the present invention, and is not of a nature of limiting the technical scope of the present invention.

### EXAMPLE 1

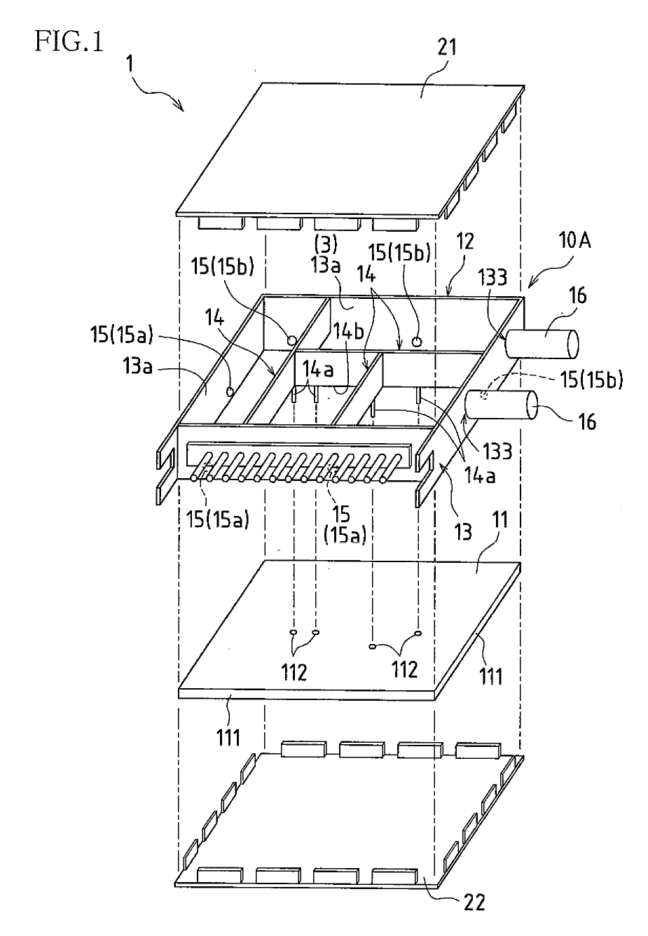

FIG. 1 is a perspective view showing a schematic configuration of a tuner unit 1 furnished with a printed circuit board securing structure 10A according to Example 1 of the present invention. The printed circuit board securing structure 10A includes a chassis 12, and a printed circuit board 11 is secured to the chassis 12.

The illustrated printed circuit board 11 is configured to be a printed circuit board having a high-frequency circuit such as a printed circuit board for receiving television signals, for example. The printed circuit board 11 is rectangular. For example, unshown components such as a resistor, a volume capacitor and the like, or an unshown air-core coil, SAW filter and the like are mounted on the circuit board 11.

The chassis 12 has a chassis frame 13 and a shield plate 14. The chassis frame 13 is a metal frame that surrounds lateral faces 111 of the periphery of the printed circuit board 11. The illustrated chassis frame 13 is formed so as to cover from all sides the lateral faces 111 of the printed circuit board 11. The shield plate 14 is a metal shield plate that partitions the space within the chassis frame 13. The shield plate 14 defines compartments that section the components mounted on the printed circuit board 11 so as to be able to electrically shield each circuit portion of the printed circuit board 11.

In the illustrated embodiment, the tuner unit 1 is further furnished with a pair of shield lids 21 and 22. The pair of shield lids 21 and 22 are provided on the chassis frame 13 so as to respectively cover one face and the other face of the printed circuit board 11. Thereby, the tuner unit 1 covers the entire printed circuit board 11 with the chassis frame 13 and the pair of shield lids 21 and 22. The chassis frame 13 and the pair of shield lids 21 and 22 form a shielding case.

The end of the shield plate 14 on the side facing the printed circuit board 11 is furnished with protrusions 14a that extend towards the printed circuit board 11. In the printed circuit board 11, protrusion-receiving holes 112 into which the protrusions 14a of the shield plate 14 are inserted are provided in lands of the printed circuit board 11. While the protrusions 14a of the shield plate 14 are inserted into the protrusion-receiving holes 112, the protrusions 14a are manually soldered on the lands of the printed circuit board 11.

And, on inner wall faces 131 of the chassis frame 13, circuit board holding parts 15 are provided for holding the printed circuit board 11 between the circuit board holding parts and the shield plate 14. The circuit board holding parts 15 are configured to be able to secure the printed circuit board 11 from the face opposite to the shield plate 14.

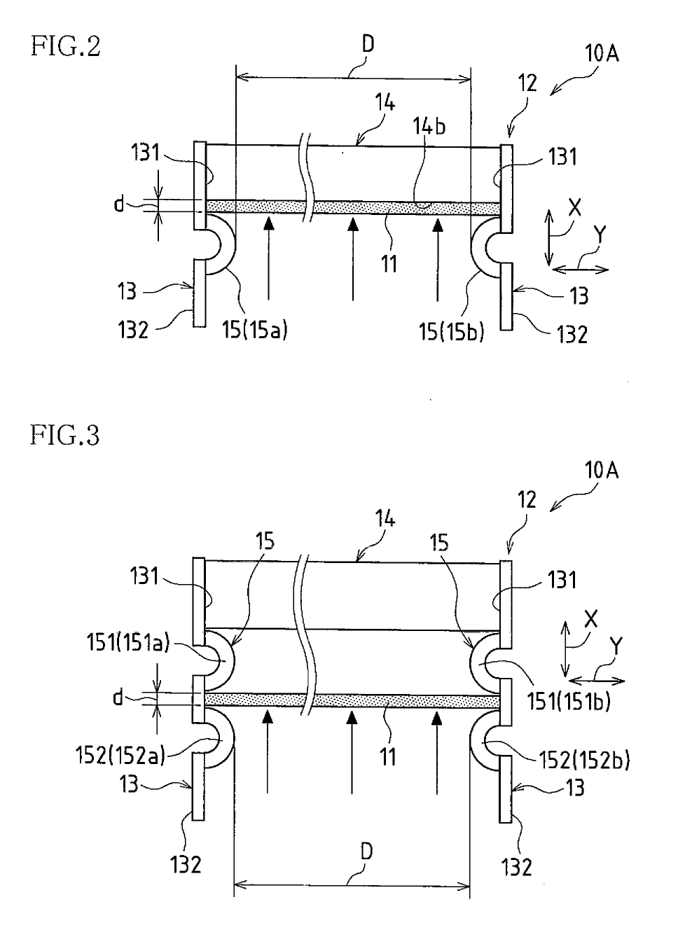

FIG. 2 is a cross-sectional view schematically showing a part of the circuit board holding parts 15 of the printed circuit board securing structure 10A shown in FIG. 1.

The printed circuit board 11 is, as shown in FIG. 2, held immovable in the direction (direction Y in the figure) perpendicular to the thickness direction of the circuit board (direction X in the figure) by the inner wall faces 131 of the chassis frame 13 as well as held immovable in the thickness direction X of the circuit board by the circuit board-side edge 14b of the shield plate 14 and the circuit board holding parts 15.

According to the printed circuit board securing structure 10A of Example 1, by disposing the circuit board holding parts 15 on the chassis frame 13, the number of protrusions 14a of the shield plate 14 and the protrusion-receiving holes 112 can be reduced compared with a conventional printed circuit board securing structure. Therefore, manually soldered portions for securing the printed circuit board 11 can be reduced. For this reason, it is possible to reduce poor soldering in the manufacturing process, and the total production costs can be kept low.

The printed circuit board securing structure 10A is described here in more detail. The circuit board holding parts 15 are elastic and formed at specific locations on the inner wall faces 131 of the chassis frame 13. The circuit board holding parts 15 are formed by press working from the external wall faces 132 of the chassis frame 13 such that the circuit board holding parts project inward, and the circuit board holding parts appear convex when viewed from inside (appear concave when viewed from outside).

The circuit board holding parts 15 are furnished with a plurality of pairs of circuit board holding parts 15a and 15b disposed at locations opposing each other. When the printed circuit board 11 is secured to the chassis 12, the printed circuit board 11 is inserted from the side opposite to the shield plate 14 of the chassis frame 13 with reference to the circuit board holding parts 15, and placed over the circuit board holding parts 15a and 15b while slightly extending the space D between the pair of circuit board holding parts 15a and 15b disposed at locations opposing each other as well as elastically deforming by deflection the circuit board holding parts 15a and 15b, thereby being fitted between the shield plate 14 and the circuit board holding parts 15a and 15b.

A space corresponding to the thickness d of the printed circuit board 11 is provided between the chassis frame 13 and the circuit board holding parts 15a and 15b, and the printed circuit board 11 is arranged in the space. Thereby, the printed circuit board 11 is securely held by the inner wall faces 131 of the chassis frame 13, the circuit board-side edge 14b of the shield plate 14, and the circuit board holding parts 15a and 15b.

Moreover, in Example 1, the circuit board holding parts 15 may be configured to be able to secure the printed circuit board 11 from the aforementioned face as well as from the other face, i.e., from both faces.

FIG. 3 is a figure showing an example, in the printed circuit board securing structure 10A shown in FIG. 1, in which the circuit board holding parts 15 are configured to be able to secure the printed circuit board 11 from both faces, and is a cross-sectional view schematically showing a circuit board holding parts 15 portion.

The circuit board holding parts 15 shown in FIG. 3 are composed of first circuit board holding parts 151 that hold one face of the printed circuit board 11, and second circuit board holding parts 152 that hold the other face of the printed circuit board 11.

The printed circuit board 11 is held immovable in the direction Y perpendicular to the thickness direction X of the circuit board by the inner wall faces 131 of the chassis frame 13 as well as held immovable in the thickness direction X of the circuit board by the first circuit board holding parts 151 and the second circuit board holding parts 152.

The first and second circuit board holding parts 151 and 152 can be formed in the same manner as the aforementioned circuit board holding parts 15. That is, the circuit board holding parts 151 and 152 are elastic and formed at specific locations on the inner wall faces 131 of the chassis frame 13. The circuit board holding parts 151 and 152 are formed by press working from the outer wall faces 132 of the chassis frame 13 such that the circuit board holding parts project inward, and the circuit board holding parts appear convex when viewed from inside (appear concave when viewed from outside).

Moreover, the circuit board holding parts 151 and 152 are furnished with a plurality of pairs of circuit board holding parts (151a and 152a) and (151b and 152b) disposed at locations opposing each other. When the printed circuit board 11 is secured to the chassis 12, the printed circuit board 11 is inserted from the side opposite to the shield plate 14 of the chassis frame 13 with reference to the circuit board holding parts 151 and 152, and placed over the second circuit board holding parts 152a and 152b while slightly extending the space D between the second circuit board holding parts 152a and 152b disposed at locations opposing each other as well as elastically deforming by deflection the second circuit board holding parts 152a and 152b, thereby being fitted between the first circuit board holding parts 151a and 151b and the second circuit board holding parts 152a and 152b.

A space corresponding to the thickness d of the printed circuit board 11 is provided between the first circuit board holding parts 151 and the second circuit board holding parts 152, and the printed circuit board 11 is arranged in the space. Thereby, the printed circuit board 11 is securely held by the inner wall faces 131 of the chassis frame 13, the first circuit board holding parts 151a and 151b, and the second circuit board holding parts 152a and 152b.

Moreover, in Example 1, one or more (two in this example) terminals 16 that are electrically connected to the printed circuit board 11 may be further provided, the chassis frame 13 may be provided with one or more through-holes 133 into which the one or more terminals 16 are each inserted, and the terminals 16 may be removably connected to the through-holes 133 of the chassis frame 13. By adopting this configuration, it is easy to share the chassis frame 13, so it is possible to save the time and effort of producing a chassis including terminals for each specification, thus enabling optional extras to be added. For example, the chassis frame can be effectively used in the production of tuner units installed in television sets and the like that can receive a plurality of types of broadcasts such as digital terrestrial television broadcasts, analog terrestrial television broadcasts, satellite broadcasts, etc.

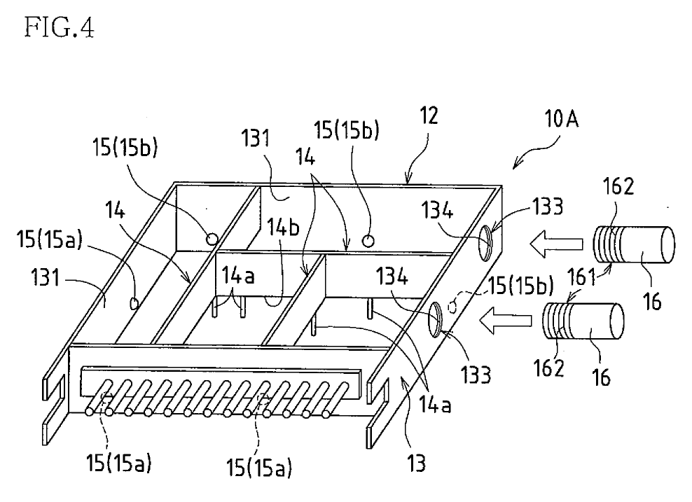

FIG. 4 is a perspective view schematically showing an example of a configuration in which, in the printed circuit board securing structure 10A shown in FIG. 1, the terminals 16 are provided insertably into and removably from the through-holes 133 of the chassis frame 13.

The printed circuit board securing structure shown in FIG. 4 is configured such that the terminals 16 and the through-holes 133 of the chassis frame 13 are fitted together by screwing. The terminals 16 are cylindrical, and external threads 162 are formed by performing screw processing on the outer periphery at the end 161 of the terminals 16 on the chassis frame 13 side. Moreover, the through-holes 133 of the chassis frame 13 are circular. Internal threads 134 are formed by performing screw processing on the inner periphery of the through-holes 133 such that the internal threads are fitted together with the external thread 162 of the terminals 16 by screwing. In the printed circuit board securing structure 10A having such a configuration, by rotating a terminal 16 in one or the other direction around the axis relative to a through-hole 133 of the chassis frame 13, the external thread 162 and the internal thread 134 are screw-fitted or released, thereby enabling the terminal 16 to be mounted on or released from the through-hole 133.

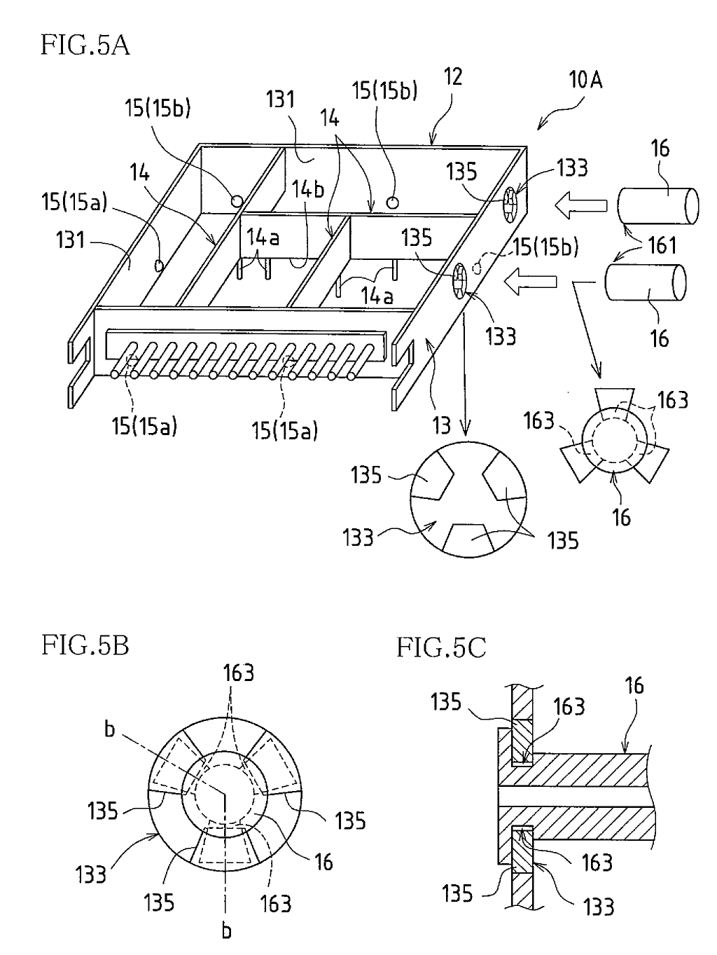

FIGS. 5A to 5C are figures schematically showing, in the printed circuit board securing structure 10A shown in FIG. 1, another example of a configuration in which the terminals 16 are provided insertably into and removably from the through-holes 133 of the chassis frame 13, in which FIG. 5A is a perspective view thereof; FIG. 5B is a side view showing a manner of engagement of a terminal 16 and a through-hole 133; and FIG. 5C is a cross-sectional view along line b-b in FIG. 5B.

In the printed circuit board securing structure shown in FIG. 5, a plurality of locking parts 135 extending in the radially inward direction are provided at a specific interval in the through-holes 133 of the chassis frame 13. At the end 161 on the side of insertion into the through-holes 133 of the terminals 16, a plurality of engagement parts 163 are provided at a specific interval in the circumferential direction. The engagement parts 163 as illustrated are formed as grooves extending in the circumferential direction. When a terminal 16 is inserted into a through-hole 133 and rotated around the axis, each engagement part 163 is engaged rotatable around the axis and immovable in the axial direction relative to the plurality of locking parts 135 disposed on the through-hole 133.

In the printed circuit board securing structure 10A having such a configuration, by rotating a terminal 16 in one or the other direction around the axis relative to a through-hole 133 of the chassis frame 13, the locking parts 135 and the engagement parts 163 are engaged at a specific engagement position or disengaged at a specific disengagement position, thereby enabling the terminal 16 to be mounted on or released from the chassis frame 13.

### EXAMPLE 2

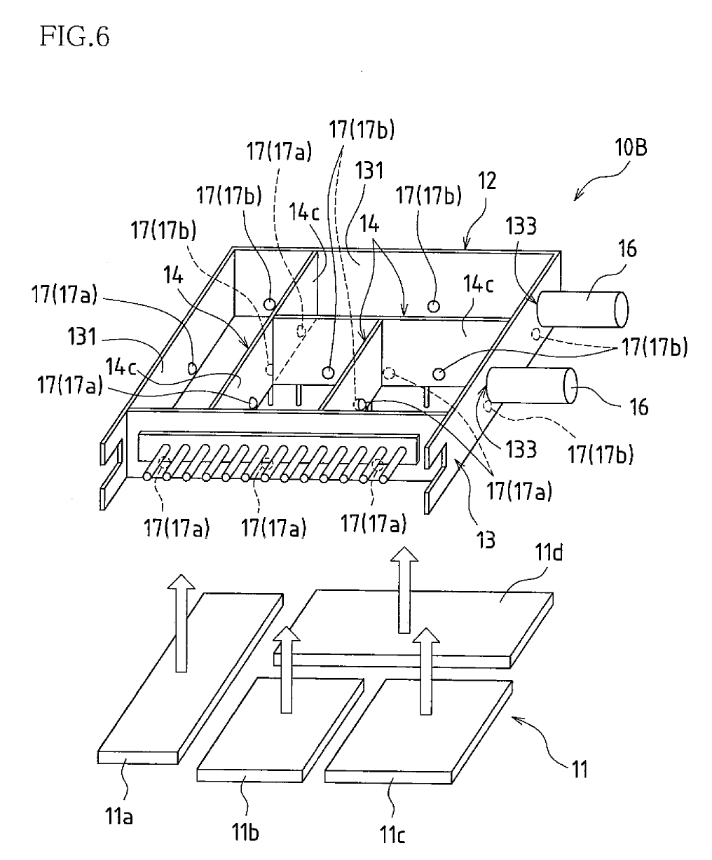

FIG. 6 is a perspective view schematically showing a configuration of a printed circuit board securing structure 10B according to Example 2 of the present invention.

In the printed circuit board securing structure 10B shown in FIG. 6, substantially the same components as in the printed circuit board securing structure 10A of Example 1 are given the same reference numbers and the description thereof is omitted.

The printed circuit board 11 is divided into pieces having sizes slightly smaller than those of the compartments partitioned by the shield plate 14. In the illustrated embodiment, the printed circuit board 11 is divided into 4 circuit board pieces 11a to 11d. Each circuit board piece 11a to 11d is arranged in a compartment partitioned by the shield plate 14.

Among the inner wall faces 131 of the chassis frame 13 and the wall faces 141 of the shield plate 14, on the faces that surround each circuit board piece 11a to 11d, circuit board holding parts 17 that are configured so as to be able to secure each circuit board piece 11a to 11d from both faces are provided.

The printed circuit board securing structure 10B of Example 2 exhibits the following effects in addition to the effects exhibited by the printed circuit board securing structure 10A of Example 1. That is, since the printed circuit board 11 is divided into pieces, when the design of a part of a circuit is changed, in addition to being able to reduce the costs of the design change, only the circuit board piece of the changed part has to be newly produced, and therefore unnecessary work such as replacement of the entire circuit board 11 due to the design change can be eliminated, so the costs of reproduction can be reduced.

The circuit board holding parts 17 can be of the same configuration as the circuit board holding parts 15 of FIG. 3 described in connection with the printed circuit board securing structure 10A of Example 1.

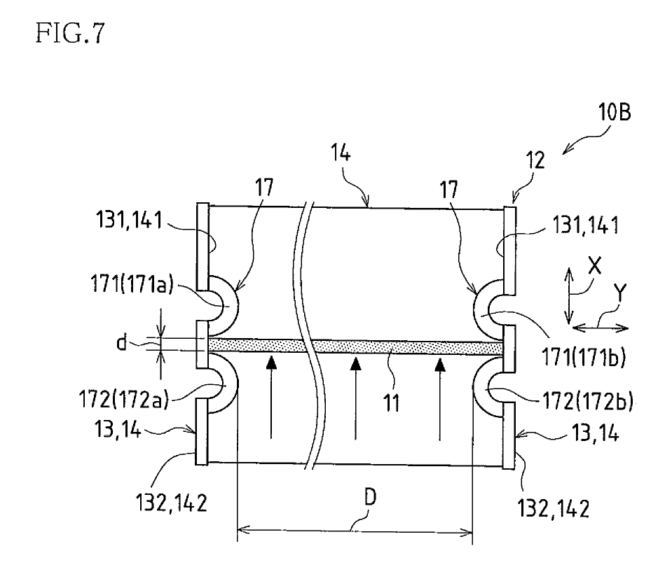

FIG. 7 shows an example of the circuit board holding parts 17 in the printed circuit board securing structure 10B shown in FIG. 6, and is a cross-sectional view schematically showing a circuit board holding parts 17 portion.

The circuit board holding parts 17 shown in FIG. 7 are composed of first circuit board holding parts 171 holding one face of each circuit board piece 11a to 11d and second circuit board holding parts 172 holding the other face of each circuit board piece 11a to 11d.

Each circuit board piece 11a to 11d is held immovable in the direction Y perpendicular to the thickness direction X of the circuit board by the faces that surround each circuit board piece 11a to 11d among the inner wall faces 131 of the chassis frame 13 and the wall faces 141 of the shield plate 14 as well as held immovable in the thickness direction X of the circuit board by the first circuit board holding parts 171 and the second circuit board holding parts 172.

The first and second circuit board holding parts 171 and 172 are elastic and formed at specific locations on the inner wall faces 131 of the chassis frame 13 and the wall faces 141 of the shield plate 14. The circuit board holding parts 171 and 172 are formed by press working from the outer wall faces 132 of the chassis frame 13 and the wall faces 142 of the shield plate 14 such that the circuit board holding parts project inward appear convex when viewed from inside (appear concave when viewed from outside).

Moreover, the circuit board holding parts 171 and 172 are furnished with a plurality of pairs of circuit board holding parts (171a and 172a) and (171b and 172b) disposed at locations opposing each other. When the printed circuit board 11 is secured to the chassis 12, the printed circuit board 11 is inserted into a compartment of the chassis frame 13 and placed over a pair of the circuit board holding parts disposed at locations opposing each other (e.g., second circuit board holding parts 172a and 172b) while slightly extending the space D between the pair of circuit board holding parts as well as elastically deforming by deflection the pair of circuit board holding parts 172a and 172b, thereby being fitted between the first circuit board holding parts 171a and 171b and the second circuit board holding parts 172a and 172b.

A space corresponding to the thickness d of each circuit board piece 11a to 11d is provided between the first and second circuit board holding parts 171 and 172, and each circuit board piece 11a to 11d is arranged in the space. Thereby, the printed circuit board 11 is securely held by the inner wall faces 131 of the chassis frame 13, the wall faces 141 of the shield plate 14, the first circuit board holding parts 171a and 171b, and the second circuit board holding parts 172a and 172b.

Also in the printed circuit board securing structure 10B of Example 2, as in the printed circuit board securing structure 10A of Example 1, the chassis frame 13 is provided with one or more through-holes 133 into which one or more terminals 16 are each inserted. The terminals 16 may be removably connected to the through-holes 133 of the chassis frame 13. Thereby, the configuration shown in FIG. 4 and FIGS. 5A to 5C can be realized.

In the configuration described above, in a state in which while the ground part of the terminals 16 and the chassis 12 are electrically connected, the signal part and the ground part of the terminals 16 and the signal part and the ground part of the printed circuit board 11 respectively are not connected, the printed circuit board 11 is attached to the chassis 12. Therefore, after attaching the printed circuit board 11 to the chassis 12, the signal part and the ground part of the terminals 16 and the signal part and the ground part of the printed circuit board 11 respectively are electrically connected.

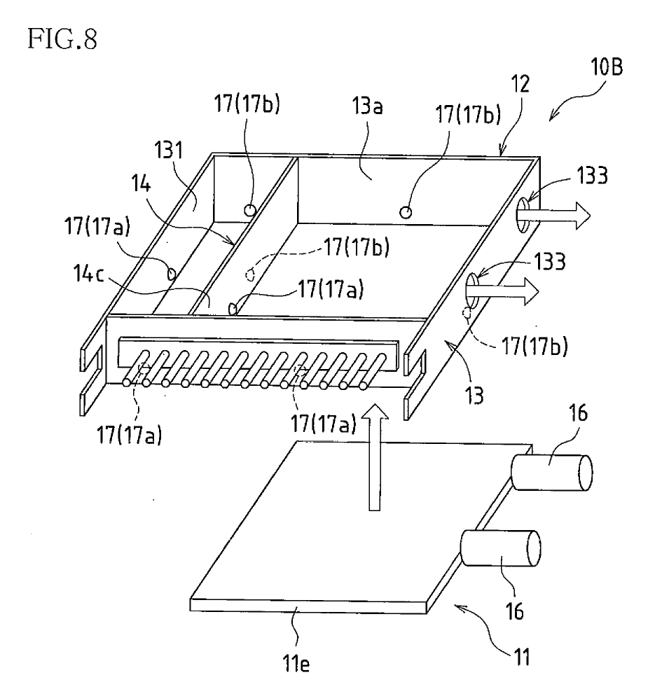

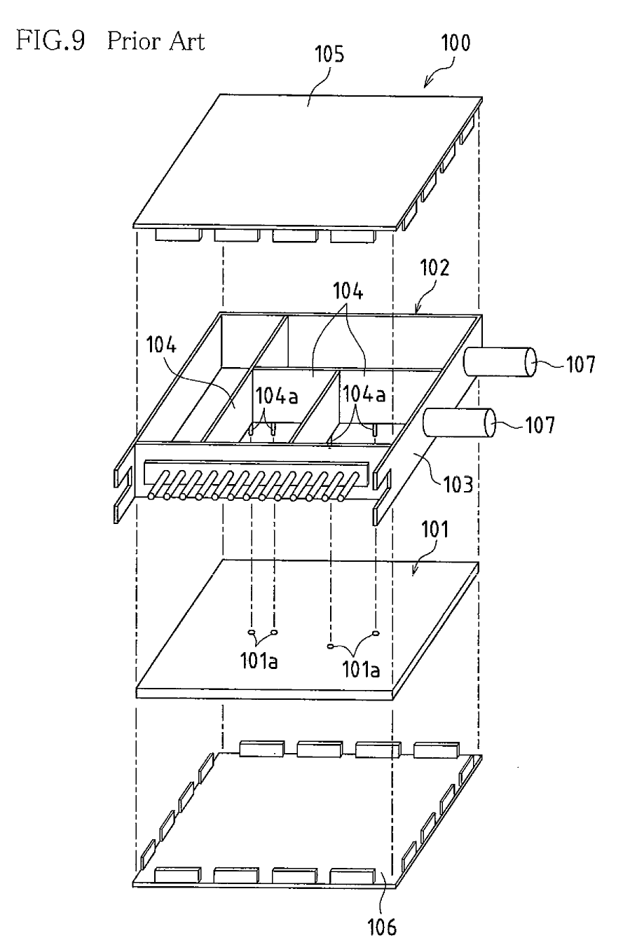

So, the printed circuit board securing structures 10A and 10B of Example 1 and Example 2 may have a configuration in which the terminals 16 are electrically connected to the signal part and the ground part of the printed circuit board 11 while being fixed to the printed circuit board 11. The through-holes 133 for inserting the terminals 16 are provided in the chassis frame 13. The terminals 16 are inserted into the through-holes 133 of the chassis frame 13 while being fixed to the printed circuit board 11. This configuration is described below with reference to FIG. 8 using the printed circuit board securing structure 10B shown in FIG. 6.

FIG. 8 is an exploded perspective view schematically showing an example of a configuration in which the terminals 16 are inserted into the through-holes 133 of the chassis frame 13 while being fixed to the printed circuit board 11 in the printed circuit board securing structure 10B shown in FIG. 6. FIG. 8 illustrates an example in which the printed circuit board 11 are divided into two pieces, and an illustration of one circuit board piece (11a) is omitted.

In the printed circuit board securing structure shown in FIG. 8, one or at least one of a plurality of the terminals 16 is electrically connected to the signal part and the ground part of the printed circuit board 11 while being fixed to the printed circuit board 11. The printed circuit board 11 to which the terminals 16 are fixed is placed in the chassis frame 13 (a compartment of the chassis frame 13 in this example) while the terminals 16 are inserted into the through-holes 133 of the chassis frame 13, and secured by the circuit board holding parts.

In the printed circuit board securing structure 10B having such a configuration, the central conductor (signal part) of the terminals 16 and the signal circuit part of the circuit board 11 (a circuit board piece 11e in this example) as well as the ground part of the terminals 16 and the ground part of the circuit board 11 (here, the circuit board piece 11e) can be electrically connected in advance, and thus it is possible to improve assembling workability.

As described above, according to the present invention, soldered portions manually provided to secure the printed circuit board 11 can be greatly reduced, thereby enabling productivity to be enhanced. Furthermore, even when the specification of the printed circuit board 11 is changed, it is possible to flexibly respond to the specification change, and thus it is possible to improve productivity.

The present invention may be embodied in various other forms without departing from the spirit or essential characteristics thereof. The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

What is claimed is:

1. A printed circuit board securing structure that secures a printed circuit board to a chassis, wherein
the chassis comprises a chassis frame that surrounds lateral faces of the printed circuit board and a shield plate that partitions a space within the chassis frame, and
circuit board holding parts for holding the printed circuit board between the circuit board holding parts and the shield plate are provided on inner wall faces of the chassis frame.

2. The printed circuit board securing structure according to claim 1, wherein the circuit board holding parts are configured to be able to secure the printed circuit board from both faces.

3. A printed circuit board securing structure that secures a printed circuit board to a chassis, wherein
the chassis comprises a chassis frame that surrounds lateral faces of the printed circuit board and a shield plate that partitions a space within the chassis frame,
the printed circuit board is divided into pieces so as to correspond to the space partitioned by the shield plate, and
among inner wall faces of the chassis frame and wall faces of the shield plate, on faces that surround each divided circuit board piece of the printed circuit board, circuit board holding parts that are configured to be able to secure each circuit board piece from both faces are disposed.

4. The printed circuit board securing structure according to any one of claims 1 to 3, wherein
a terminal that is electrically connected to the printed circuit board is further provided,
a through-hole into which the terminal is inserted is disposed in the chassis frame, and
the terminal is provided so as to be insertable into and removable from the through-hole of the chassis frame.

5. The printed circuit board securing structure according to claim 4, wherein the terminal and the through-hole of the chassis frame are configured to be fitted together by screwing.

6. The printed circuit board securing structure according to claim 4, wherein
a plurality of locking parts extending in a radially inward direction are provided in a circumferential direction in the through-hole of the chassis frame, and
at the end of the terminal on the side of insertion into the through-hole, a plurality of engagement parts are provided in a circumferential direction in which when the terminal is inserted into the through-hole and rotated around the axis, the terminal is engaged rotatably around the axis and immovably in the axial direction with the plurality of the locking parts in the through-hole.

7. The printed circuit board securing structure according to any one of claims 1 to 3, wherein
a terminal that is electrically connected to the printed circuit board and is fixed to the printed circuit board is further provided,
a through-hole into which the terminal is inserted is disposed in the chassis frame, and
the terminal is inserted into the through-hole of the chassis frame while being fixed to the printed circuit board.

8. A tuner unit comprising the printed circuit board securing structure according to any one of claims 1 to 3.
